(19) United States
(12) Patent Application Publication
(10) Pub. No.: US 2012/0024344 A1
(43) Pub. Date: Feb. 2, 2012

(54) Photovoltaic solar cell overlay

(75) Inventor: Michael Stephen Evanbar, Torrance, CA (US)

(73) Assignee: Rensselaer Polytechnic

(21) Appl. No.: 12/804,702

(22) Filed: Jul. 28, 2010

(51) Int. Cl. H01L 31/052

(52) U.S. Cl. 136/246

(57) ABSTRACT

This abstract describes a simple, low-cost device to improve power yields provided by fixed solar panel installations without the need to precisely position optical elements above the panel or add solar tracking and array positioning systems. The device utilizes one or more layers of optically refractive and/or diffractive materials imbued with specific contours and/or optical characteristics. The device is bonded directly to the solar array's sun-facing surface either as the array is manufactured, or retro-fitted to the array after installation. The device and bond interfaces may be comprised of any suitable optically high-transmittance material with refractive indices sufficiently higher than that of air. Additional gains in solar array power yields are made possible by the use of transparent, variable-contoured overlays or fluid-filled polymeric film overlays with modifiable optical characteristics which adapt to sun angle.

### RELATED APPLICATIONS

The present application is related to U.S. Pat. No. 452,496, issued Jul. 3, 2008, for DESIGN AND FABRICATION OF A LOCAL CONCENTRATOR SYSTEM, by Dutta, Partha, included by reference herein.

Assigned to Rensselaer Polytechnic

### FIELD OF THE INVENTION

The present invention relates a device for improving solar array power yields, and more particularly, for capturing solar energy at incident sun angles normally unavailable to fixed-position installations.

### BACKGROUND OF THE INVENTION

The current state-of-the-art for solar power installations relies on costly and complex sun-tracking systems. These solar power systems constantly monitor the movement of the sun to maintain an optimum angle to the incident sun energy. In fact, the power produced by photovoltaic solar cells is limited to the cosine of the cell's incident angle to the sun. For example, when the sun's incident angle falls off from 0 degrees directly overhead to −60 degrees in the afternoon, only 50% of the sun's energy-producing power can be realized by fixed solar array installations.

Although sun-tracking equipment installed on solar arrays can increase viable output by up to 100%, it is not practical for many commercial and residential solar power applications to install or retro-fit such vectoring systems. The cost and complexity of such systems would be prohibitive. For this reason, it is current practice for most applications to accept the loss of efficiency as the incident sun angle falls off from being directly overhead. It is common for solar arrays to have fixed mounts that tilt the array and face due South in the Northern Hemisphere (in the Southern Hemisphere, they typically point due North). The tilt angle, from horizontal, can be varied for season, but if fixed, is typically set to give optimal array output during the peak electrical demand portion of a typical year. Even so, fixed mount installations can lose as much as half the power available due to the fact that solar cell power output decays rapidly as the incident sun angle the increases.

Photovoltaic modules often have a sheet of glass on the sun-facing side, allowing light to pass while protecting the semiconductor wafers from the elements (rain, hail, etc.). Solar Concentrators have been proposed by Dutta (Partha) to concentrate and direct solar energy on to an array of solar (photovoltaic) cells. Their patent, assigned to Rensselaer Polytechnic (U.S. Pat. No. 452,496), proposed that a series of optical elements be mounted above the solar array such that the directed sunlight follows a path along the array as the sun traverses the sky during the day without the need to vector the optical element.

Sun-tracking systems are used for state-of-the-art solar powered applications and primarily to power one-of-a-kind experiments where cost is not a prohibiting factor. These solar power applications incorporate complex systems requiring sun-tracking sensors linked to attitude control servo mechanisms.

Although solar cell modules usually are protected by a thin sheet of glass on sun facing side, the glass does not improve performance of the array at high sun angles.

The Rensselaer Polytechnic device is intended to concentrate solar energy on a part of the array and thus provide a greater yield per given array size. This device cannot maintain optimum sun angles on the solar cells. Moreover, the Rensselaer device adds considerable expense and complexity, requiring optical elements and additional support structures mounted above the array in a precise attitude and position. The energy-concentrating optical elements will absorb a portion of the energy and the support structure itself will shadow some of the sun from the solar array. When even a small portion of a solar cell, module, or array is shaded while the remainder is in sunlight, the output falls off dramatically due to internal ‘short-circuiting’ (the electrons reversing course through the shaded portion of the p-n junction). Therefore it is extremely important that an installation is not shaded at all.

The sun-tracking sensors and solar panel attitude control mechanisms currently in use are not practical for most commercial and residential applications because of their cost and complexity.

It would be advantageous to provide a solar power amplifying device that is made an integral, permanent part of a solar array panel and does not require any additional support structure, positioning equipment or positioning skills.

It would also be advantageous to provide a solar power amplifying device that serves to “ruggedize” the photovoltaic array itself by sealing the photovoltaic cells from the environment and reducing the potential of shock or vibration fracture.

It would further be advantageous to provide a simple, low-cost device that negates the deleterious impact of high incident sun angles on power yield for fixed solar panel installations.

It would further be advantageous to provide a simple, low-cost device to autonomously improve solar array performance based on information sensed solely by the solar array.

It would further be advantageous to provide a device that can be retrofitted to existing solar array panels to enhance their performance.

It would further be advantageous to provide a solar power amplifying device that will not require any significant maintenance or adjustment after installation.

### SUMMARY OF THE INVENTION

In accordance with the present invention, there is provided an add-on device for photovoltaic solar cells to capture solar energy normally unavailable at high incident sun angles. The device does not require precise positioning of optical elements above the array, sun sensors, or solar array panel vectoring mechanisms. The concept described herein is neither complex nor costly and thus advances the state-of-the-art for commercial and residential applications.

One or more layers of optically transparent refracting or diffracting media is overlaid and joined without interceding space to the sun-facing side of a photovoltaic cell, array or panel. When light passes from one transparent medium to another, it bends according to Snell's law. Thus, any incident solar energy impinging on the device at angles other than directly overhead will be bent towards the solar cell's normal axis as the light ray enters the overlay and is transmitted through the overlay to the solar cell.

In most simplistic form, the device is comprised of a transparent solar cell array overlay imbued with specific optical characteristics and/or surface contours. The solar cell array overlay may be comprised of any transparent material such as glass, optical grade acrylics, polymers, or any other suitable high-transmittance media with refractive or diffractive indices or other optical characteristics suitable for re-directing the incident sun energy towards the normal to the plane of the device. The overlays also may be constructed from or contain gas, fluid, or plastic materials and be capable of adjusting contours or optical characteristics using sun angle, thermal or sensed solar power output as control devices. Generally, the solar array overlays will consist of two types; a fixed configuration type produced from fixed-form materials such as optical-grade glass or acrylics, and a variable configuration or variable optics type which may employ thermally-sensitive gas or fluids contained in optical-grade acrylic film. The function of either overlay type is to re-direct impinging sun energy so as to improve solar cell power yields at higher sun angles.

### BRIEF DESCRIPTION OF THE DRAWINGS

A complete understanding of the present invention may be obtained by reference to the accompanying drawings, when considered in conjunction with the subsequent, detailed description, in which:

FIG. 1 is a chart illustrating how power produced by a solar array varies with the solar cell's sensed sun angle;

FIG. 2 is a chart that illustrates the impact of adding a refracting flat glass overlay to the solar array's sun facing side on sensed sun angle at varying sun-incident angles;

FIG. 3 is a chart that illustrates the impact of adding a refracting flat glass overlay to the solar array's sun facing side at varying sun-incident angles on power output (neglecting the impact of transmission loss due to energy absorption);

FIG. 4 is a chart that incorporates the impact of a realistic absorption loss (ko=0.92) on power output for a glass plate solar array overlay with varying sun-incident angles;

FIG. 5 is a front detail view of a two-stage variable optics overlay installed on a solar array to manage the impact of daily sun angle transit on power production;

FIG. 6 is a chart that compares the power produced by a two-stage variable optics overlay with that of a glass plate solar array overlay and an unfitted solar array;

FIG. 7 is a front detail view of a pivoting wave contoured overlay installed on a solar array to manage the impact of daily sun angle transit on power production;

FIG. 8 is a chart comparing the power produced by a pivoting wave contoured overlay with that of a flat glass plate fitted and an unfitted solar array;

FIG. 9 is a chart defining the pivot angle versus sun angle schedule assumed for the power production comparison in FIG. 8;

FIG. 10 is an exploded view of a typical solar array overlay showing the base layer, the sun-facing surface layer, the surface layer coating, and the overlay-to-solar array interface; and

FIG. 11 is a detail view of a solar array overlay illustrating high incident-angle energy being trapped between the bond and surface layer and thereby minimizing the impact of internal reflection on the solar array.

For purposes of clarity and brevity, like elements and components will bear the same designations and numbering throughout the Figures.

### DESCRIPTION OF THE PREFERRED EMBODIMENT

The purpose of the solar array overlay device is to capture solar energy normally unavailable to a fixed-position solar array at higher incident sun angles. Power produced by un-vectored solar power applications drops off sharply in the morning and afternoon due to the higher sun incident angles encountered. The device described herein utilizes one or more layers of transparent media joined in-plane to the solar array and imbued with specific optical characteristics capable of bending incident light towards the normal to the plane of the attached device. The overlays are comprised of light-bending optical materials such as dense glass, optical grade acrylics, polymers, or any other suitable high-transmittance media with adequate refractive, diffractive, or reflective characteristics. For typical terrestrial applications, the device layers are bonded to one-another and to the solar array without an air gap at the overlay-to-solar array interface. Any suitable bonding adhesive with adequate optical transmittance and refractive characteristics may be used.

In simplest form, the device contains an optically-refracting overlay core layer 14 bonded without air gap to the solar array on one side and to an overlay sun-facing surface layer 10 on the other side. The bond between the device and the solar array comprises the overlay-to-solar array interface layer 18. When light passes from one transparent medium to another, it bends according to Snell's law. Thus, any incident sun angle other than directly overhead will be bent towards the solar cell's normal axis by refraction as the light ray enters the overlay, provided that the overlay's index of refraction is higher than that of air. However, in order for the overlay to capture solar energy at very high sun angles approaching 90 degrees, two additional factors may be incorporated into the device:

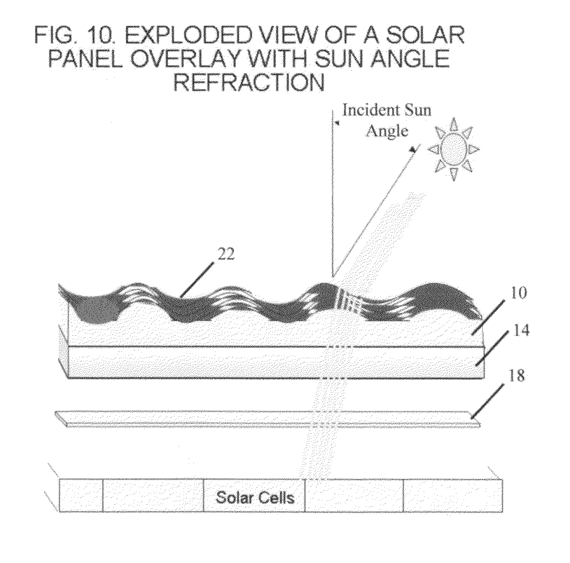

1. The overlay's sun-facing surface may be contoured as shown in FIGS. 10 to delay the onset of the critical angle (total internal reflection where all energy is reflected off the surface layer) and to capture more high sun-angle energy.

2. The bond layer at the solar array interface and the core layer itself will possess refractive indices greater than that of the overlay's sun-facing surface layer to assure that solar energy entering the core layer at high incident sun angles is reflected back off the surface layer to the solar array.

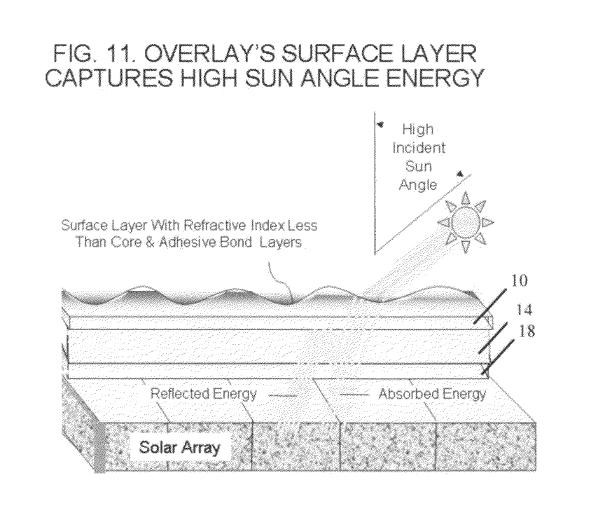

Thus, the physics dictating the trapping of high sun-angle energy in the overlay's core layer is the same for the core of an optical wave guide and is illustrated in FIG. 11. The relative variance between core and surface layer refractive indices need not be large, and thus is easily attainable in a multitude of materials. For example, typical values for core and cladding refractive indices in an optical waveguide are 1.48 and 1.46, respectively. Also, a diffracting or refracting surface layer coating 22 may be added to the overlay sun-facing surface layer 10 to modify the characteristics of the surface layer as shown in FIG. 10.

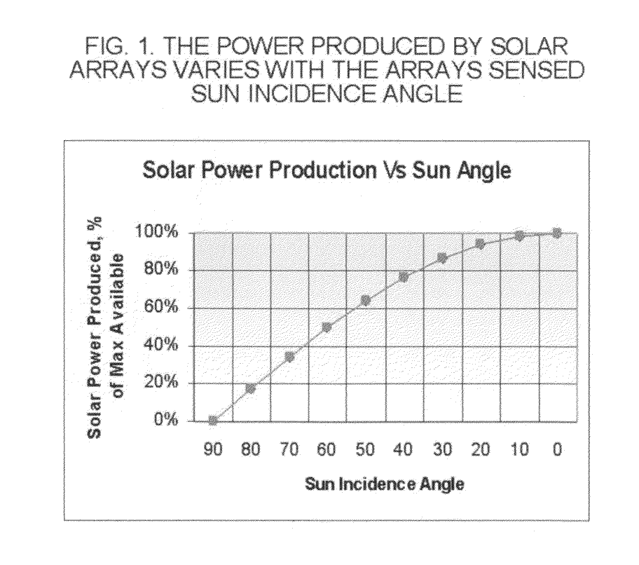

Snell's Law was used to estimate the effect of a refracting overlay on the array's sensed sun angle. Assuming a refractive index of 1.5 for the overlay, the calculation verifies that at an incident sun angle of 45 degrees, the overlay is capable of reducing the sun angle sensed by the array to less than 30 degrees. FIG. 1 illustrates how a simple, refracting flat glass overlay can reduce the solar cell's sensed sun angle as the sun transits overhead.

Next, acknowledging the fact that solar power output decays with the cosine of the sun angle sensed by the array, the power gained by adding a refractive overlay may be calculated by re-phrasing Snell's law:

Po=Ko*Cos(Ar)=Ko*Cos(ArcSin[Ni*Sin(Ai)/Nr]) where Ko represents transmittance, the fraction of incident light at a specified wavelength that is not absorbed and passes through the glass overlay.

The unfitted array power output is represented by:

P=K*Cos(Ai), where K will be assumed equal to 1.0 for the purpose of this comparison.

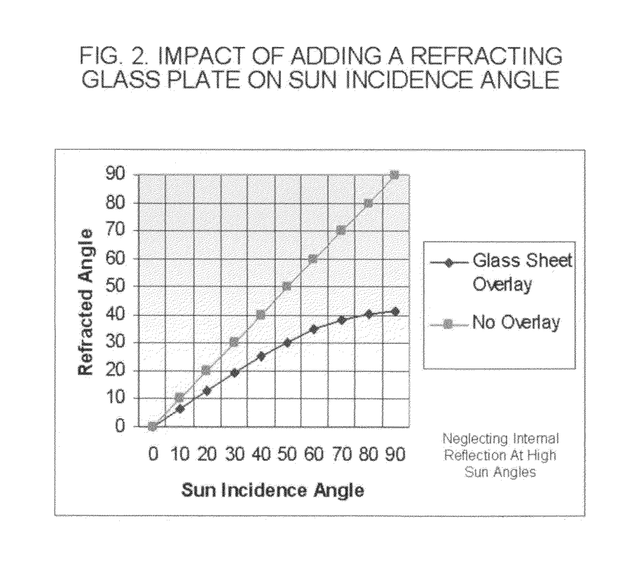

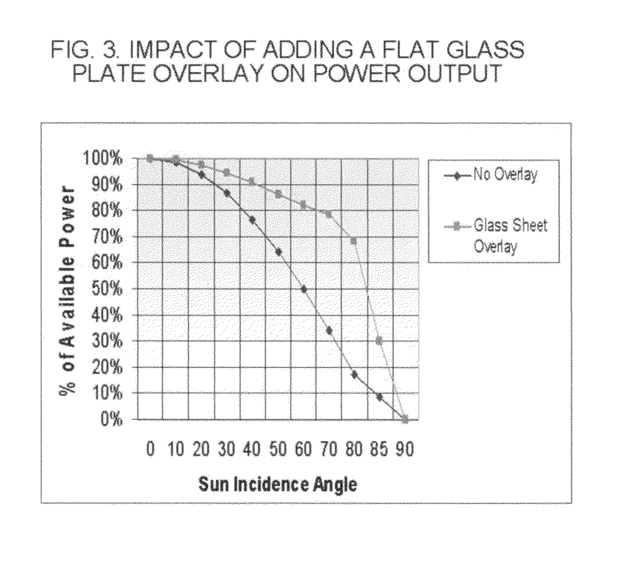

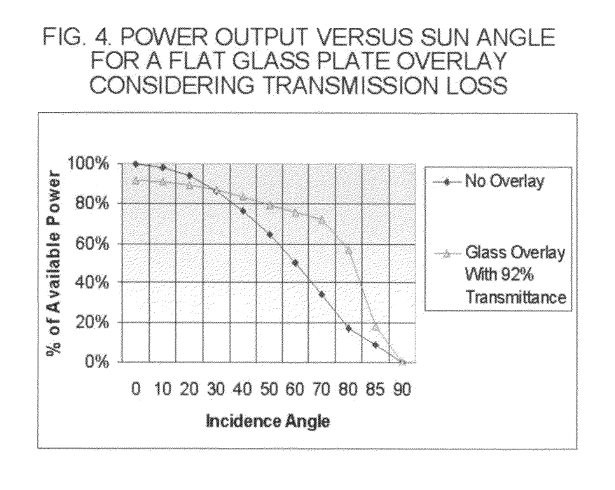

Using these relationships, it may be concluded that the most significant relative power gains attributable to the overlay occur at incident sun angles over 45 degrees, which are the most troublesome for un-vectored solar power applications. FIG. 2 illustrates the beneficial effect of adding an overlay core layer 14 in the form of a flat glass plate to a solar array on power output at varying sun-incident angles (Neglecting the impact of transmission loss due to energy absorption). FIG. 3 compares the power produced by arrays with and without the overlay core layer 14 as a function of sun angle, neglecting the impact of absorption loss (Ko=1.0). FIG. 4 incorporates a realistic absorption loss (Ko=0.92) on the base layer power comparison, indicating that the small loss incurred at low sun angles due to the overlay's energy absorption is more than recovered by the large power gains at higher sun angles.

Variable Type Solar Array Overlays

Variable Type Overlay devices are intended to adjust either their optical characteristics or modify sun-facing surface contours in “real time” as a function of sun position, and thus essentially track the sun at higher sun angles without the cost and complexity of conventional sensors and sun-tracking systems. The following discussion of several mechanisms that may be used in the device for activating changes in contour or optics is provided for illustrative purposes and does not preclude the use of other mechanisms for activating device modifications.

For the purpose of adjusting optical characteristics, polymers easily can be processed into thin films of high optical quality, can be modified easily by chemical doping, and are compatible with integrated circuit processing techniques, making them ideal for use in the solar array overlay device. Polymer photorefractive systems being developed today can potentially yield even larger maximum refractive index changes. Employing polymerics, fluids, gases or plastic materials with variable contour or variable optical characteristics for the overlay can boost high sun-angle performance over that of fixed-type overlays. The mechanisms by which the index of refraction of a material can be modified in response to an incident optical beam include photochromism, thermochromism, thermo refraction, and excited state generation. If the overlay material is also electro-optic, then the index of refraction may be changed with an applied external electric field. Thus, it becomes feasible for the overlay's index of refraction to be regulated by the solar array itself.

Polymeric overlays with high refractive indices in a normal state appear ideal for use in the device at high incident sun angles even though they may slightly reduce power yields at low sun-incident angles. These materials would warm in response to more direct solar energy at progressively lower sun angles (or alternately in response to a solar array “increased power output trigger”). On warming, they either modify contour (flatten in shape) or modify their optical characteristics (refractive or diffractive indices), allowing the mid-day sun to transit the overlay with minimal sun angle deflection and absorption. At higher sun angles again later in the day, the materials would cool and return to their normal (high-sun angle) state.

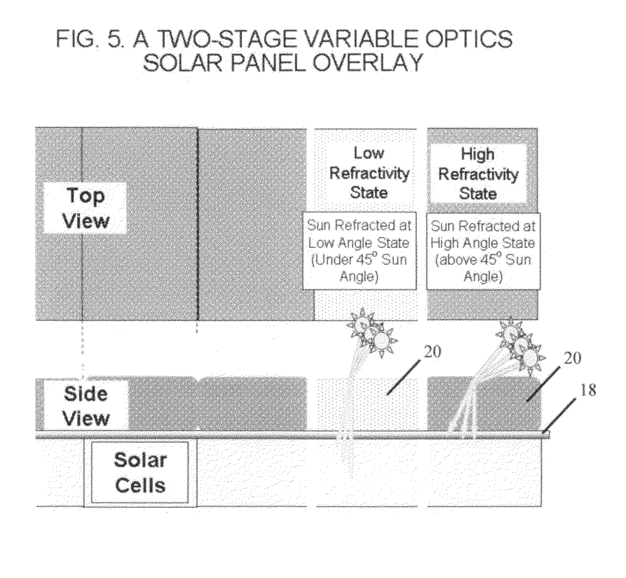

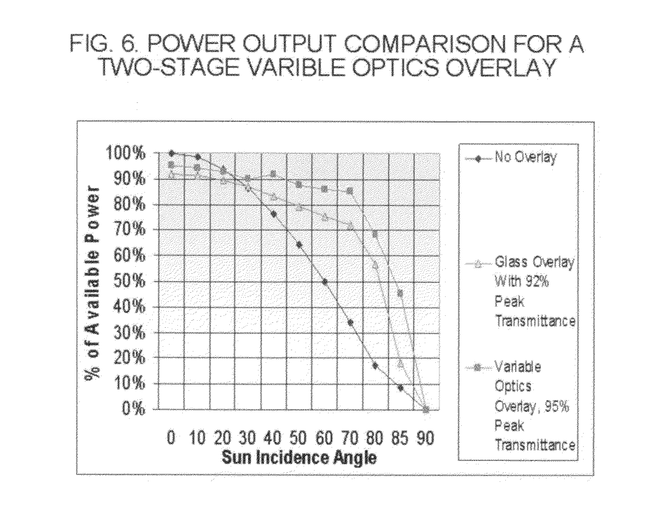

FIG. 5 depicts an alternate variable optics surface layer 20 overlay which incorporates two-stages, one above and one below 45 degrees of sun angle. This “dynamic” overlay is installed on a solar array to manage the impact of daily sun angle transit on power production. For the purposes of comparison, the overlay material in a normal state is assumed to have refractive indices of 1.8 with a transmittance of 0.92, but is calibrated to change state in response to incident sun angles below 45 degrees to a refractive index of 1.5 and transmittance of 0.95. FIG. 6 compares the power produced by this variable optics surface layer and an unfitted array. FIG. 6 indicates that the device will provide most power gains at sun angles above 50 degrees.

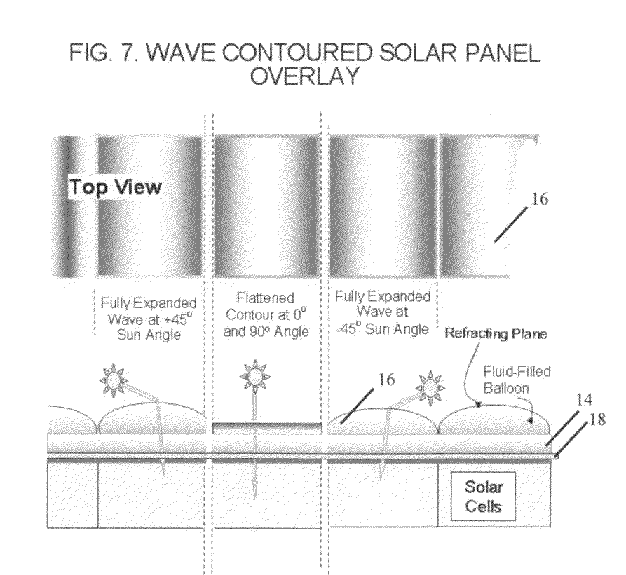

FIG. 7 depicts an alternate variable contour surface layer 16 overlay comprised of cylindrical sections that alternately extend and flatten in response to daily sun angle cycles. Full extension occurs at sun angles of +45 or −45 degrees and the device progressively flattens near +/−90 and 0 degrees of sun angles. This “wave shaped” surface contour incorporates an adjustable overlay sun-facing surface layer 10 designed to continuously refract the sun towards the solar cell's normal axis when the solar panel is installed in an East-West facing direction. For purposes of illustration, the expansion and contraction mechanism depicted in FIG. 7 employs a thermally-sensitive gas or fluid-filled polymeric or acrylic film that alternately expands and contracts in response to sun angle heating and cooling. However, any suitable optically-refracting material and activation technique may be used to implement the required surface contour changes with sun angle.

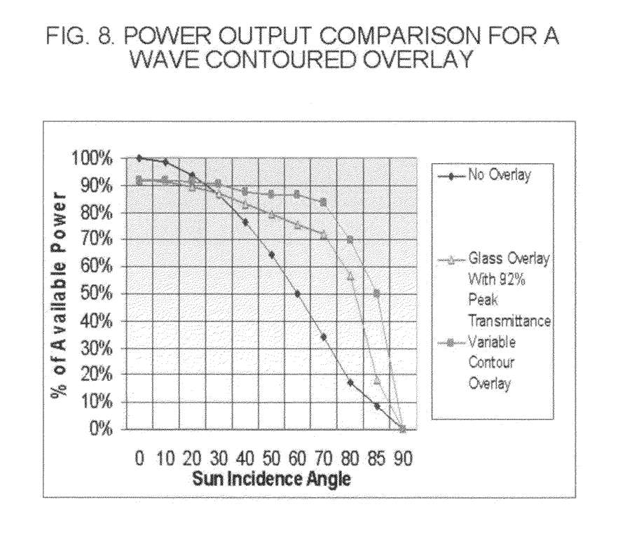

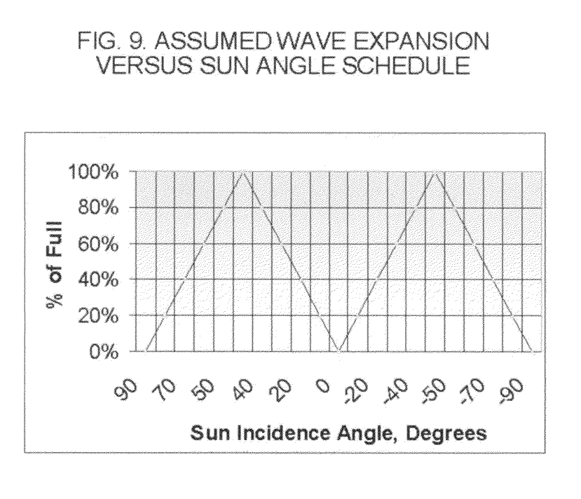

FIG. 8 compares the power produced by a variable wave-contoured overlay with that of a refracting glass plate (overlay core layer 14) and an unfitted solar array. In order to provide a realistic performance comparison, a varying optical transmittance ranging from a peak of 92% at low sun angles down to 50% at high sun angles was assumed for the calculation. FIG. 9 illustrates the expansion and contraction cycle for the alternate variable contour surface layer 16 power comparison shown in FIG. 8.

Since other modifications and changes varied to fit particular operating requirements and environments will be apparent to those skilled in the art, the invention is not considered limited to the example chosen for purposes of disclosure, and covers all changes and modifications which do not constitute departures from the true spirit'and scope of this invention.

Having thus described the invention, what is desired to be protected by Letters Patent is presented in the subsequently appended claims.

What is claimed is:

1. A photovoltaic solar cell overlay for re-directing the incident solar energy on photovoltaic cell arrays so as to improve moderate to high sun-angle performance, comprising:
means for refracting and transmitting incident sun energy to the overlay core layer while minimizing total reflection at high sun angles;
means for accepting incident solar energy from the sun-facing surface layer, refracting to better align with the solar cell's normal plane, and transmitting through the bond interface to the solar cell, rigidly bonded to said means for refracting and transmitting incident sun energy to the overlay core layer while minimizing total reflection at high sun angles;
means for autonomously optimizing refracted sun angles for high, medium, and low incident sun angles by employing variable sun-facing contours and transmitting adjusted sun angles to the core layer, rigidly bonded to said means for accepting incident solar energy from the sun-facing surface layer, refracting to better align with the solar cell's normal plane, and transmitting through the bond interface to the solar cell;
means for attaching the overlay to the solar array while transmitting solar energy captured at all sun angles by the overlay with minimal reflection or absorption loss, rigidly bonded to said means for accepting incident solar energy from the sun-facing surface layer, refracting to better align with the solar cell's normal plane, and transmitting through the bond interface to the solar cell;
means for autonomously optimizing refracted sun angles for high, medium and low incident sun angles by adapting optical characteristics to accommodate varying sun angles, rigidly bonded to said means for accepting incident solar energy from the sun-facing surface layer, refracting to better align with the solar cell's normal plane, and transmitting through the bond interface to the solar cell; and
means for supplementing the sun angle bending capability of the sun-facing surface layer, rigidly connected to said means for refracting and transmitting incident sun energy to the overlay core layer while minimizing total reflection at high sun angles.

2. The photovoltaic solar cell overlay in accordance with claim 1, wherein said means for refracting and transmitting incident sun energy to the overlay core layer while minimizing total reflection at high sun angles comprises a transparent, high transmittance, surface contoured, refractive or diffractive overlay sun-facing surface layer.

3. The photovoltaic solar cell overlay in accordance with claim 1, wherein said means for accepting incident solar energy from the sun-facing surface layer, refracting to better align with the solar cell's normal plane, and transmitting through the bond interface to the solar cell comprises a transparent, high transmittance, constant shape, un-contoured, highly refractive or diffractive overlay core layer.

4. The photovoltaic solar cell overlay in accordance with claim 1, wherein said means for autonomously optimizing refracted sun angles for high, medium, and low incident sun angles by employing variable sun-facing contours and transmitting adjusted sun angles to the core layer comprises a transparent, variable contoured, high transmittance, refractive or diffractive alternate variable contour surface layer.

5. The photovoltaic solar cell overlay in accordance with claim 1, wherein said means for attaching the overlay to the solar array while transmitting solar energy captured at all sun angles by the overlay with minimal reflection or absorption loss comprises an overlay attach surface, high transmittance, refractive bond layer overlay-to-solar array interface layer.

6. The photovoltaic solar cell overlay in accordance with claim 1, wherein said means for autonomously optimizing refracted sun angles for high, medium and low incident sun angles by adapting optical characteristics to accommodate varying sun angles comprises a transparent, adaptable optics, high transmittance, refractive or diffractive alternate variable optics surface layer.

7. The photovoltaic solar cell overlay in accordance with claim 1, wherein said means for supplementing the sun angle bending capability of the sun-facing surface layer comprises a diffracting or refracting, optically transparent, high transmittance surface layer coating.

8. A photovoltaic solar cell overlay for re-directing the incident solar energy on photovoltaic cell arrays so as to improve moderate to high sun-angle performance, comprising:
a transparent, high transmittance, surface contoured, refractive or diffractive overlay sun-facing surface layer, for refracting and transmitting incident sun energy to the overlay core layer while minimizing total reflection at high sun angles;
a transparent, high transmittance, fixed shape, un-contoured, highly refractive or diffractive overlay core layer, for accepting incident solar energy from the sun-facing surface layer, refracting to better align with the solar cell's normal plane, and transmitting through the bond interface to the solar cell, rigidly bonded to said overlay sun-facing surface layer;
a transparent, variable contoured, high transmittance, refractive or diffractive alternate variable contour surface layer, for autonomously optimizing refracted sun angles for high, medium, and low incident sun angles by employing variable sun-facing contours and transmitting adjusted sun angles to the core layer, rigidly bonded to said overlay core layer;
an overlay attach surface, high transmittance, refractive bond layer overlay-to-solar array interface layer, for attaching the overlay to the solar array while transmitting solar energy captured at all sun angles by the overlay with minimal reflection or absorption loss, rigidly bonded to said overlay core layer;
a transparent, adaptable optics, high transmittance, refractive or diffractive alternate variable optics surface layer, for autonomously optimizing refracted sun angles for high, medium and low incident sun angles by adapting optical characteristics to accommodate varying sun angles, rigidly bonded to said overlay core layer; and
a diffracting or refracting, optically transparent, high transmittance surface layer coating, for supplementing the sun angle bending capability of the sun-facing surface layer, rigidly connected to said overlay sun-facing surface layer.

9. A photovoltaic solar cell overlay for re-directing the incident solar energy on photovoltaic cell arrays so as to improve moderate to high sun-angle performance, comprising:
a transparent, high transmittance, surface contoured, refractive or diffractive overlay sun-facing surface layer, for refracting and transmitting incident sun energy to the overlay core layer while minimizing total reflection at high sun angles;
a transparent, high transmittance, fixed shape, un-contoured, highly refractive or diffractive overlay core layer, for accepting incident solar energy from the sun-facing surface layer, refracting to better align with the solar cell's normal plane, and transmitting through the bond interface to the solar cell, rigidly bonded to said overlay sun-facing surface layer;
a transparent, variable contoured, high transmittance, refractive or diffractive alternate variable contour surface layer, for autonomously optimizing refracted sun angles for high, medium, and low incident sun angles by employing variable sun-facing contours and transmitting adjusted sun angles to the core layer, rigidly bonded to said overlay core layer;
an overlay attach surface, high transmittance, refractive bond layer overlay-to-solar array interface layer, for attaching the overlay to the solar array while transmitting solar energy captured at all sun angles by the overlay with minimal reflection or absorption loss, rigidly bonded to said overlay core layer;
a transparent, adaptable optics, high transmittance, refractive or diffractive alternate variable optics surface layer, for autonomously optimizing refracted sun angles for high, medium and low incident sun angles by adapting optical characteristics to accommodate varying sun angles, rigidly bonded to said overlay core layer; and
a diffracting or refracting, optically transparent, high transmittance surface layer coating, for supplementing the sun angle bending capability of the sun-facing surface layer, rigidly connected to said overlay sun-facing surface layer.
